(19) United States
(12) Patent Application Publication
(10) Pub. No.: US 2008/0038913 A1
(43) Pub. Date: Feb. 14, 2008

(54) METHODS OF FORMING ALUMINUM-FREE WIRE BOND PAD AND PAD SO FORMED

(75) Inventors: Mukta G. Farooq, Hopewell Junction, NY (US); Robert Hannon, Wappingers Falls, NY (US); Ian D. Melville, Highland, NY (US); Kevin S. Petrarca, Newburgh, NY (US); Donna S. Zupanski-Nielsen, Yorktown Heights, NY (US)

Correspondence Address: HOFFMAN, WARNICK & D'ALESSANDRO LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 11/463,642

(22) Filed: Aug. 10, 2006

(51) Int. Cl. H01L 21/44

(52) U.S. Cl. 438/612

(57) ABSTRACT

Methods of forming an aluminum-free wire bond pad and the pad so formed are disclosed. In one embodiment, the method includes forming an opening through a dielectric layer to a last metal of a chip; forming a tantalum nitride (TaN) layer over the chip and over the opening; removing the tantalum nitride (TaN) layer outside of the opening; forming a passivation mask layer over the chip including a passivation mask opening over the last metal; forming a titanium tungsten (TiW) layer and a copper (Cu) layer over the chip; forming a mask layer over the chip including a mask opening to the copper (Cu) layer over the last metal; forming a nickel (Ni) layer and a copper (Cu) layer and then a gold (Au) layer in the mask opening; and removing the mask.

### BACKGROUND OF THE INVENTION

1. Technical Field

The invention relates generally to semiconductor fabrication, and more particularly, to methods of forming an aluminum-free wire bond pad and the pad so formed.

2. Background Art

In the semiconductor industry, aluminum (Al) has been eliminated in all back end of line structures, i.e., those that scale upwardly the size of wiring from the transistor structures, except for the final connection stack. In particular, aluminum (Al) is typically used in the final connection stack for wire bond connection chips because, inter alia, it exhibits suitable bonding to gold (Au) wire. A final connection stack to a last metal layer within a chip may include, for example, tantalum nitride (TaN), tantalum (Ta), titanium nitride (TiN) and aluminum layers. However, as new technologies evolve that continually decrease the size of semiconductor devices (such as those that generate wiring at a 45 nm dimension), the presence of aluminum (Al) in the final connection stack creates a number of problems. First, it may create increased cost for wire bond connection chips. More specifically, aluminum (Al) elimination from all chips that employ controlled collapse chip connection (C4) is common. As a result, only those products using wire bond connections from the chip will bear the cost of aluminum (Al) tooling, thus increasing the costs of those chips. Second, the smaller wiring dimensions may impact yield if the aluminum (Al) thickness has to increase in order to address electromigration (EM) concerns. In particular, with shrinking x-y dimensions of wiring, patterning a steeper aspect ratio aluminum (Al) stack is a more difficult proposition from a manufacturability perspective, which may impact yield. Third, aluminum (Al) continues to present environmental concerns because of toxic chemicals associated with chromium-phosphorous cleaning of aluminum (Al). Thus, there are strong reasons to eliminate aluminum (Al) entirely from back end of line structures and, in particular, the final connection stack for a wire bond chip product.

### SUMMARY OF THE INVENTION

Methods of forming an aluminum-free wire bond pad and the pad so formed are disclosed. In one embodiment, the method includes forming an opening through a dielectric layer to a last metal of a chip; forming a tantalum nitride (TaN) layer over the chip and over the opening; removing the tantalum nitride (TaN) layer outside of the opening; forming a passivation mask layer over the chip including a passivation mask opening over the last metal; forming a titanium tungsten (TiW) layer and a copper (Cu) layer over the chip; forming a mask layer over the chip including a mask opening to the copper (Cu) layer over the last metal; forming a nickel (Ni) layer and a copper (Cu) layer and then a gold (Au) layer in the mask opening; and removing the mask.

A first aspect of the invention provides a method of forming an aluminum-free wire bond pad, the method comprising: forming an opening through a dielectric layer to a last metal of a chip; forming at least one first layer over the chip and over the opening, wherein the at least one first layer is selected from the group consisting of: tantalum nitride (TaN), titanium (Ti) and titanium nitride (TiN); removing the at least one first layer outside of the opening; forming a passivation mask layer over the chip including a passivation mask opening to the at least one first layer over the last metal; forming at least one second layer over the chip and over the passivation mask opening, wherein the at least one second layer is selected from the group consisting of: titanium tungsten (TiW), copper (Cu) and titanium (Ti); and forming at least one third layer and then a gold (Au) layer over at least a part of the at least one second layer, wherein the at least one third layer is selected from the group consisting of: nickel (Ni), copper (Cu), ruthenium (Ru) and nickel-platinum (NiPt).

A second aspect of the invention provides an aluminum-free wire bond pad comprising: an opening to a last metal of a chip; at least one first layer in the opening coupled to the last metal, wherein the at least one first layer is selected from the group consisting of: tantalum nitride (TaN), titanium (Ti) and titanium nitride (TiN); at least one second layer over the at least one first layer in the opening, wherein the at least one second layer is selected from the group consisting of: titanium tungsten (TiW), copper (Cu) and titanium (Ti); at least one third layer over the at least one second layer in the opening, wherein the at least one third layer is selected from the group consisting of: nickel (Ni), copper (Cu), ruthenium (Ru) and nickel-platinum (NiPt); and a gold (Au) layer over the at least one third layer.

A third aspect of the invention provides a method of forming an aluminum-free wire bond pad, the method comprising: forming an opening through a dielectric layer to a last metal of a chip; forming a tantalum nitride (TaN) layer over the chip and over the opening; removing the tantalum nitride (TaN) layer outside of the opening; forming a passivation mask layer over the chip including a passivation mask opening over the last metal; forming a titanium tungsten (TiW) layer and a copper (Cu) layer over the chip; forming a mask layer over the chip including a mask opening to the copper (Cu) layer over the last metal; forming a nickel (Ni) layer and a copper (Cu) layer and then a gold (Au) layer in the mask opening; and removing the mask layer.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIGS. 1-9 show embodiments of a method according to the invention.

FIG. 6 shows an aluminum-free wire bond pad according to one embodiment of the invention.

FIG. 8 shows an aluminum-free wire bond pad according to another embodiment of the invention.

FIG. 9 shows an aluminum-free wire bond pad according to another embodiment of the invention.

It is noted that the drawings of the invention are not to scale. The drawings are intended to depict only typical aspects of the invention, and therefore should not be considered as limiting the scope of the invention.

### DETAILED DESCRIPTION

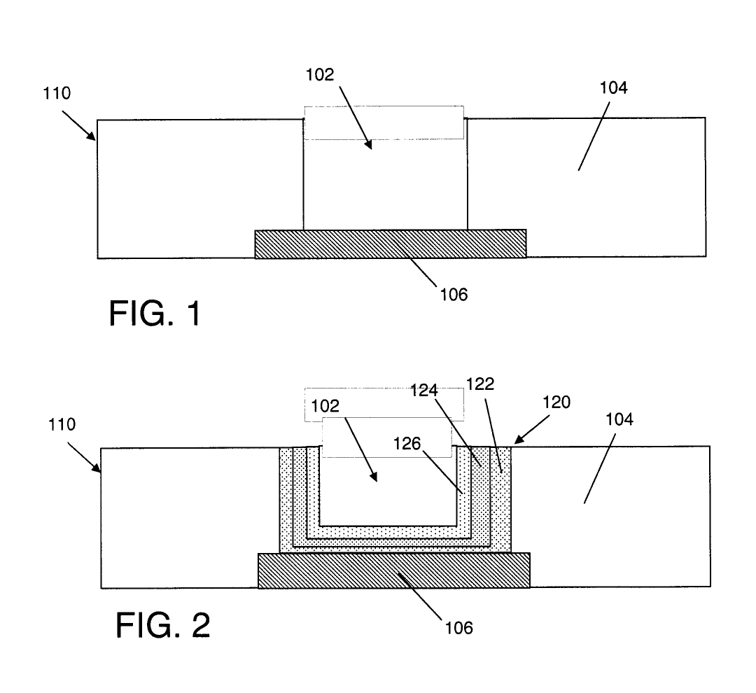

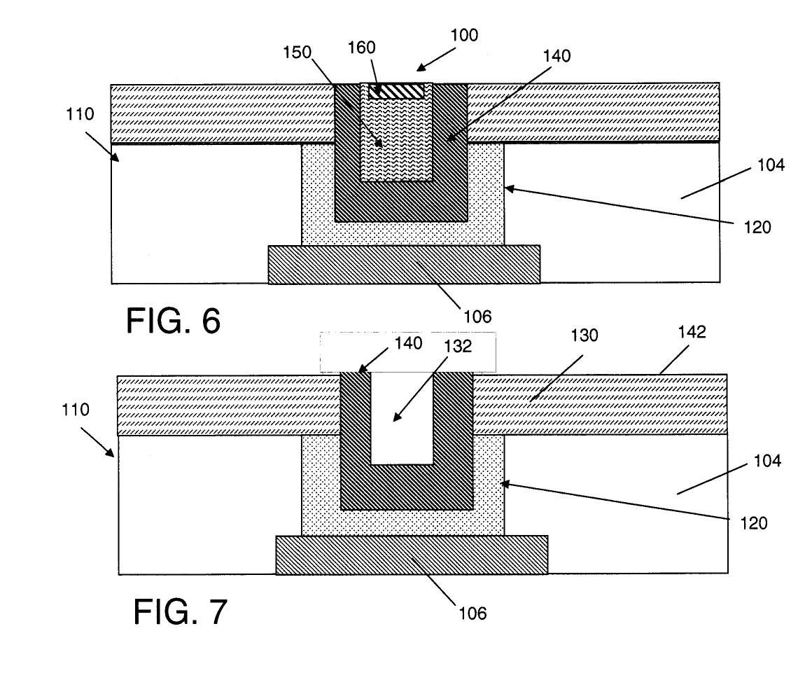

Turning to the drawings, FIGS. 1-9 illustrate embodiments of a method of forming an aluminum-free wire bond pad 100 (FIGS. 6, 8 and 9). In the drawings, only one pad 100 (FIGS. 6, 8 and 9) is shown; it is understood, however, that the teachings of the invention may be used in multiple locations on a wafer. It is also understood that for clarity sake that particular cross-hatching will be used to denote different materials, i.e., the cross-hatching for a particular material changes within the drawings.

In FIG. 1, an opening 102 is formed through a dielectric layer 104 to a last metal 106 of a chip 110. Opening 102 may be formed in any now known or later developed manner, e.g., depositing, patterning and etching a mask (not shown) and then forming opening 102. Dielectric layer 104 may include any now known or later developed interlayer dielectric such as silicon nitride (Si₃N₄), silicon oxide (SiO₂), fluorinated SiO₂ (FSG), hydrogenated silicon oxycarbide (SiCOH), porous SiCOH, etc., or combinations of the above. Last metal 106 may include any conductive metal such as copper (Cu). Other details of chip 110 have not been shown for clarity.

In FIG. 2, at least one first layer 120 is formed over chip 110 and over opening 102. While FIG. 2 shows three layers 120, other numbers of layers may be used as will be described further herein. At least one first layer 120 may include, for example: tantalum nitride (TaN), titanium and/or titanium nitride (TiN). In one embodiment, at least one first layer 120 includes only a tantalum nitride (TaN) layer 122. In another embodiment, at least one first layer 120 may include a titanium (Ti) layer 124 and a titanium nitride (TiN) layer 126 over TiN layer 122. At least one first layer 120 may be formed by, for example, sputtering and/or plating. FIG. 2 also shows removing at least one first layer 120 outside of opening 102, e.g., by chemical mechanical polishing (CMP). In subsequent drawings, only one layer for at least one first layer 120 is shown for clarity.

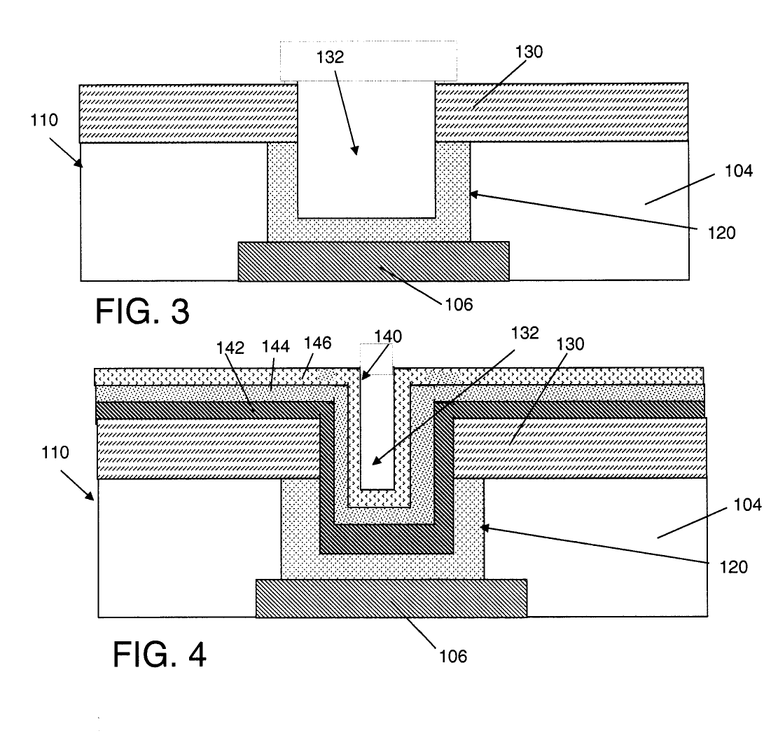

FIG. 3 shows forming a passivation mask layer 130 over chip 110 including a passivation mask opening 132 to at least one first layer 120 over last metal 106. In one embodiment, passivation mask layer 130 may include a photosensitive polyimide (PSPI), and mask opening 132 may be formed by a reactive ion etch (RIE). Other materials, e.g., silicon oxide (SiO₂), and mask opening forming techniques may also be employed.

FIG. 4 shows forming at least one second layer 140 over passivation mask opening 132. While FIG. 4 shows three layers 140, other numbers of layers may be used as will be described further herein. At least one second layer 140 may include, for example: titanium tungsten (TiW), copper (Cu) and/or titanium (Ti). In one embodiment, as shown in FIG. 4, at least one second layer 140 includes a titanium tungsten (TiW) layer 142 and a copper (Cu) layer 144, i.e., outer layer 146 is omitted. In another embodiment, at least one second layer 140 includes titanium tungsten (TiW) layer 142, a titanium tungsten (TiW) layer 144 and a copper (Cu) layer 146. In subsequent drawings, only one layer for at least one second layer 140 is shown for clarity.

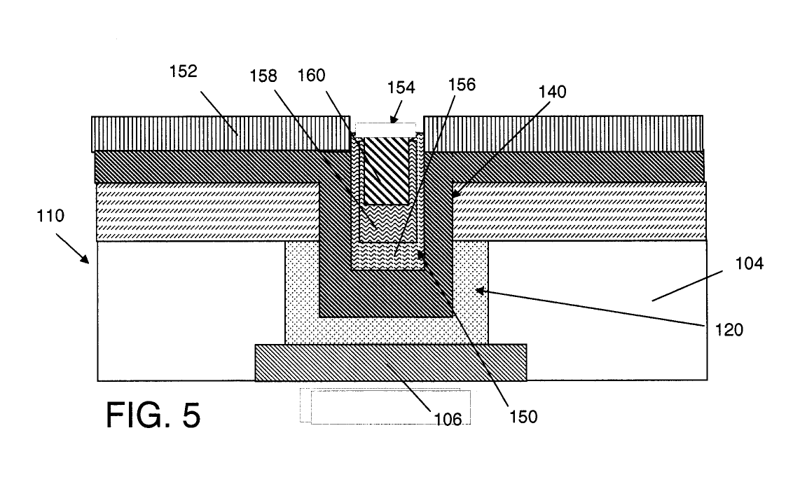

FIG. 5 shows forming at least one third layer 150 and a gold (Au) layer 160 over at least one second layer 140. In particular, a photoresist mask 152 is formed over at least one second layer 140 over last metal 106. Photoresist mask 152 includes a mask opening 154. At least one third layer 150 and gold (Au) layer 160 are formed through mask opening 154. In the embodiment shown, at least one third layer 150 and gold (Au) layer 160 may be electrolytically plated in opening 154. At least one third layer 150 may include nickel (Ni), copper (Cu), ruthenium (Ru) and/or nickel-platinum (NiPt). In one embodiment, shown in FIG. 5, at least one third layer 150 includes a single layer 156 of, for example: a nickel (Ni) or nickel platinum (NiPt) layer or ruthenium (Ru), i.e., layer 158 is omitted. In another embodiment, also shown in FIG. 5, at least one third layer 150 may include a copper (Cu) layer 156 and a nickel (Ni) layer 158. In subsequent drawings, only one layer for at least one third layer 150 is shown for clarity.

FIG. 6 shows removing photoresist mask 152 (FIG. 5) and portions of layers 140, 150 and 160. Photoresist mask 152 may be removed using any now known or later developed stripping techniques, e.g., wet etching. A further seed etch may also be performed at this stage, if necessary, prior to bonding a gold wire (not shown) to wire bond pad 100.

Turning to FIGS. 7-9, an alternative embodiment of the above-described method is shown. This embodiment starts at the structure shown in FIG. 3. FIG. 7 shows forming at least one second layer 140 in passivation mask opening 132. At least one second layer 140 may include any of the above-described embodiments. In this embodiment, at least one second layer 140 is polished, e.g., by chemical mechanical polishing (CMP), to a surface 142 of mask 130.

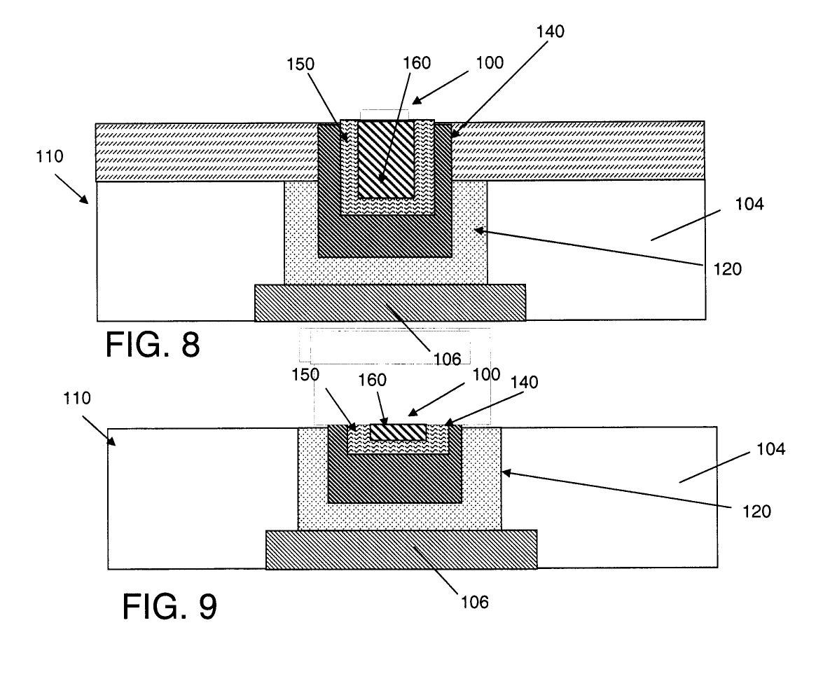

FIG. 8 shows forming at least one third layer 150 and gold (Au) layer 160 over passivation mask opening 132 (FIG. 7). In this embodiment, at least one third layer 150 and gold (Au) layer 160 may be electrolessly plated through passivation mask opening 132 (FIG. 7). Processing may stop at this stage, if desired, resulting in wire bond 100. Alternatively, as shown in FIG. 9, passivation mask layer 130 (FIG. 7) may be removed, along with portions of layers 140, 150 and 160. Passivation mask layer 130 (FIG. 7) may be removed using any now known or later developed techniques, e.g., CMP. A further seed etch may also be performed at this stage, if necessary, prior to bonding a gold wire (not shown) to wire bond pad 100.

As shown in FIGS. 6, 8 and 9, in one embodiment, an aluminum-free wire bond pad 100 is provided including: opening 102 (FIG. 1) to last metal 106 of chip 110; at least one first layer 120 in opening 102 coupled to last metal 106; at least one second layer 140 over at least one first layer 120 in opening 102; and a gold (Au) layer 160 over at least one second layer 140. As described above, at least one first layer 120 may include, for example: tantalum nitride (TaN), titanium (Ti) and/or titanium nitride (TiN); at least one second layer 140 may include, for example: titanium tungsten (TiW), copper (Cu) and titanium (Ti); and at least one third layer 150 may include, for example: nickel (Ni), copper (Cu), ruthenium (Ru) and nickel-platinum (NiPt). Aluminum-free wire bond pad 100 provides a stable solid-state diffusion bond usable with gold (Au) wire. Diffusion barrier materials (e.g., tantalum nitride (TaN), titanium tungsten (TiW), titanium nitride (TiN)) used herein will ensure that there is no copper (Cu) diffusion from the underlying last metal 106 towards, for example, nickel (Ni) layer 156 (FIG. 6) and gold (Au) layer 160. It should be understood nickel (Ni) or nickel (Ni) alloys such as nickel platinum (NiP), nickel boron (NiB) and nickel vanadium (NiV), or other suitable alloys of nickel (Ni) can be used in place of or in conjunction with the nickel (Ni) and nickel platinum (NiPt) noted in these embodiments.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A method of forming an aluminum-free wire bond pad, the method comprising:
forming an opening through a dielectric layer to a last metal of a chip;
forming at least one first layer over the chip and over the opening, wherein the at least one first layer is selected from the group consisting of: tantalum nitride (TaN), titanium (Ti) and titanium nitride (TiN);
removing the at least one first layer outside of the opening;
forming a passivation mask layer over the chip including a passivation mask opening to the at least one first layer over the last metal;
forming at least one second layer over the chip and over the passivation mask opening, wherein the at least one second layer is selected from the group consisting of: titanium tungsten (TiW), copper (Cu) and titanium (Ti); and
forming at least one third layer and then a gold (Au) layer over at least a part of the at least one second layer, wherein the at least one third layer is selected from the group consisting of: nickel (Ni), copper (Cu), ruthenium (Ru) and nickel-platinum (NiPt).

2. The method of claim 1, wherein the at least one first layer includes a tantalum nitride (TaN) layer.

3. The method of claim 2, wherein the at least one first layer further includes a titanium (Ti) layer and a titanium nitride (TiN) layer over the tantalum nitride (TaN) layer.

4. The method of claim 1, wherein the at least one second layer includes a titanium tungsten (TiW) layer and a copper (Cu) layer.

5. The method of claim 1, wherein the at least one second layer includes a titanium layer, a titanium tungsten (TiW) layer and a copper (Cu) layer.

6. The method of claim 1, wherein the at least one third layer includes one of the group consisting of: a nickel (Ni) layer, a copper (Cu) layer and a nickel (Ni) layer, a nickel platinum (NiPt) layer, or a ruthenium (Ru) layer.

7. The method of claim 1, further comprising forming a mask over the at least one second layer, the mask including a mask opening to the at least one second layer over the last metal, wherein the at least one third layer and the gold layer are formed through the mask opening, and
further comprising removing the mask after the at least one third layer and gold (Au) layer forming.

8. The method of claim 7, wherein the at least one third layer and the gold layer forming includes electrolytic plating through the mask opening.

9. The method of claim 1, wherein the at least one third layer and the gold layer forming includes electroless plating through the passivation mask opening.

10. The method of claim 9, further comprising removing the passivation mask layer.

11. An aluminum-free wire bond pad comprising:
an opening to a last metal of a chip;
at least one first layer in the opening coupled to the last metal, wherein the at least one first layer is selected from the group consisting of:
tantalum nitride (TaN), titanium (Ti) and titanium nitride (TiN);
at least one second layer over the at least one first layer in the opening, wherein the at least one second layer is selected from the group consisting of: titanium tungsten (TiW), copper (Cu) and titanium (Ti);
at least one third layer over the at least one second layer in the opening, wherein the at least one third layer is selected from the group consisting of: nickel (Ni), copper (Cu), ruthenium (Ru) and nickel-platinum (NiPt); and
a gold (Au) layer over the at least one third layer.

12. The aluminum-free wire bond pad of claim 11, wherein the at least one first layer includes a tantalum nitride (TaN) layer.

13. The aluminum-free wire bond pad of claim 11, wherein the at least one first layer further includes a titanium (Ti) layer and a titanium nitride (TiN) layer over the tantalum nitride (TaN) layer.

14. The aluminum-free wire bond pad of claim 11, wherein the at least one second layer includes a titanium tungsten (TiW) layer and a copper (Cu) layer.

15. The aluminum-free wire bond pad of claim 11, wherein the at least one second layer includes a titanium layer, a titanium tungsten (TiW) layer and a copper (Cu) layer.

16. The aluminum-free wire bond pad of claim 11, wherein the at least one third layer includes one of the group consisting of: a nickel (Ni) layer, a copper (Cu) layer and a nickel (Ni) layer, a nickel platinum (NiPt) layer, or a ruthenium (Ru) layer.

17. The aluminum-free wire bond pad of claim 11, further comprising a passivation layer including an opening through which the at least second layer, the at least third layer and the gold (Au) layer extend.

18. A method of forming an aluminum-free wire bond pad, the method comprising:
forming an opening through a dielectric layer to a last metal of a chip;
forming a tantalum nitride (TaN) layer over the chip and over the opening;
removing the tantalum nitride (TaN) layer outside of the opening;
forming a passivation mask layer over the chip including a passivation mask opening over the last metal;
forming a titanium tungsten (TiW) layer and a copper (Cu) layer over the chip;
forming a mask layer over the chip including a mask opening to the copper (Cu) layer over the last metal;
forming a nickel (Ni) layer and a copper (Cu) layer and then a gold (Au) layer in the mask opening; and
removing the mask layer.

19. The method of claim 18, wherein the nickel layer, the copper layer and the gold layer forming includes electrolytic plating.

20. The method of claim 18, further comprising removing the passivation mask layer.
